(19) United States
(12) Patent Application Publication
(10) Pub. No.: US 2006/0066926 A1
(43) Pub. Date: Mar. 30, 2006

(54) Color transforming device using brightness information of image and display device and the method thereof

(75) Inventors: Young-shin Kwak, Suwon-si (KR); Du-sik Park, Suwon-si (KR); Won-hee Choe, Gyeonggi-do (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/225,126

(22) Filed: Sep. 14, 2005

(30) Foreign Application Priority Data
Sep. 24, 2004 (KR) 10-2004-0077073

(51) Int. Cl. G03F 3/08

(52) U.S. Cl. 358/518

(57) ABSTRACT

A color transforming device using brightness information of an image and a display device having the same are disclosed. The color transforming device includes a color transformation memory for storing coefficient information in order to process a color transformation of an input image based on brightness of the input image; and a color transformation processing unit for correcting a color of the input image by using the coefficient information stored in the color transformation memory and outputting the color corrected input image. The present invention provides a color transforming method suitable to a display device automatically controlling output brightness according to brightness of input image by performing a color transformation according to the brightness of input image. When the present invention is implemented to the PDP, color information of input image signal is accurately reproduced by performing the color transformation according to the APC level of input image.

### CROSS-REFERENCE TO RELATED APPLICATIONS

This application claims the benefit under 35 U.S.C. § 119 (a) from Korean Patent Application No.10-2004-0077073 filed on Sep. 24, 2004 in the Korean Intellectual Property Office, the disclosure of which is incorporated herein by reference.

### BACKGROUND OF THE INVENTION

1. Field of the Invention

The present invention generally relates to a device for performing color transformation by using brightness information of an image and a display apparatus having the device. More particularly, the present invention relates to a color transforming device for performing color transformation of an input image according to an auto power control (APC) level of the input image in a plasma display panel (PDP) having an auto power control (APC) function automatically controlling a brightness of an image, and a PDP operating apparatus having the color transforming device.

2. Description of the Related Art

Recently, a TV home shopping program and an electric commercial transaction have been popular. Also, customers have frequently used not only a personal computer (PC) but also a television (TV) for shopping goods from the TV home shopping programs or Internet shopping malls. Accordingly, it has been required for a television to accurately reproduce color information of a broadcasting signal for showing characteristics of goods to the customers. However, a color reproduced by a display device may differ from a natural color of a good because the display device has unique primary or gamma characteristics which are different from the primary or gamma characteristics of the broadcasting signal.

Many studies have been actively progressed for reproducing an exact color of goods on a cathode-ray tube (CRT) or a liquid crystal display (LCD) monitors. Meanwhile, a plasma display panel (PDP) has become a main stream of a big size display apparatus, but color reproduction and color calibration for the PDP needs more research.

The PDP is one of display elements reproducing image data of an input electric signal by arranging a plurality of electric discharging cells in a form of a matrix and selectively activating the electric discharging cells. The PDP includes a plurality of pairs of a scan electrode and a sustain electrode. The pairs of the scan electrode and the sustain electrode are arranged in parallel and the scan electrode and the sustain electrode face each other. The PDP further includes at least one address electrode which is orthogonally arranged to the scan electrode and the sustain electrode within a predetermined space. A discharge occurs at a cross point where the pair of the scan electrode and the sustain electrode and the address electrode cross by supplying a scanning pulse voltage to at lease one of the scan electrode or the sustain electrode, and an address voltage to the address electrode. The discharging operation generates an address operation varying electric characteristics of the cross point and the timing of the discharge. After varying the electric characteristics and the discharge timing, a sustain pulse voltage is applied between the scan electrode and the sustain electrode for generating a sustain operation discharging a location where electric characteristics of the scan electrode and the sustain electrode are varied.

Generally, one frame is divided to a plurality of subfields having a sustain pulse corresponding to a weight of an image input bit by using visual characteristics of a human, and each subfield is turned on or off according to each data in order to display a gray scale of cell. One of representative methods for displaying image on the PDP is an address display separation (ADS) method.

The PDP consumes a lot of electric power. Accordingly, the PDP must include a large capacity electric power supply and the circuitry increases in size. It becomes an obstacle to reduce a size of the PDP because the PDP is generally manufactured as wall-mounted, wafer-thin, compact, and thin shape, being one of major advantage of the PDP. Also, a price of a circuit board of the PDP would be increased.

To address the above-mentioned disadvantages of the PDP, an auto power control (APC) function is implemented for the PDP. The APC function automatically controls the electric consumption according to brightness of an image. That is, the APC function determines whether image data is a dark image or a bright image and reduces the number of sustain pulse for displaying the image data when the image data is bright image.

As the PDP uses the APC function controlling brightness of image for reducing a heating value of a screen of the PDP, it must be considered for color reproduction and color transformation in the PDP in order to accurately reproduce color of image.

### SUMMARY OF THE INVENTION

Additional aspects and/or advantages of the invention will be set forth in part in the description which follows and, in part, will be apparent from the description, or may be learned by practice of the invention.

Accordingly, the present general inventive concept has been made to solve the above-mentioned and/or problems, and an aspect of the present general inventive concept is to provide a color transforming device for transforming color by using brightness information of an image.

It is another aspect of the present invention to provide a PDP operating device for performing a color transformation according to an APC level of input image.

In accordance with an aspect of the present invention, there is provided a color transforming device, including a color transformation memory for storing coefficient information in order to process a color transformation of an input image corresponding to brightness of the input image; and a color transformation processing unit for correcting a color of the input image by using the coefficient information stored in the color transformation memory and outputting the color corrected input image.

The color transforming device may be included in a display device.

In accordance with another aspect of the present invention, there is provided a plasma display panel (PDP) operating device, including a color transforming device having: a color transformation memory for storing coefficient information in order to process a color transformation of an input image corresponding to an auto power control (APC) level of the input image; and a color transformation processing unit for correcting a color of the input image by using the coefficient information corresponding to the APC level of the input image, which is provided from the color transformation memory, and outputting the color corrected input image.

The plasma display panel (PDP) operating device may further include an APC level controlling unit for detecting a load factor by using a RGB image signal input from external, determining the APC level required for operating a plasma display panel (PDP) based on the detected load factor and providing information of the determined APC level to the color transformation memory; and an address data generating unit for generating address data corresponding to the color corrected input image input signal from the color transformation processing unit.

The color transformation memory may store the coefficient information in the form of a look-up table corresponding to the APC level and the color transformation processing unit may include a first gamma transformation unit for outputting a linear RGB image signal transformed according to a gamma characteristic of an input digital RGB image signal; a color transformation matrix unit for generating a color transformed linear RGB image signal suitable for a plasma display panel (PDP) by performing a predetermined matrix transformation of the linear RGB image signal from the first gamma transformer and outputting the color transformed linear RGB image signal; and a second gamma transformation unit for transforming the color transformed linear RGB image signal to a digital RGB image signal according to a gamma characteristic of a PDP by using the look-up table of the APC level stored in the color transformation memory.

The color transformation matrix unit may use a predetermined matrix for the matrix transformation and the predetermined matrix may be varied according to the APC level.

The input digital RGB image signal may be an 8-bit signal and may have a value in a range of 0 to 255.

The color transformation memory may store coefficient information according to an APC level stored in the form of a look-up table for correcting a gamma characteristic and plural of matrix information according to an APC level for color transformation and the color transformation processing unit may include a gamma correction unit for generating a PDP digital image signal corrected to have identical gamma character comparing to an input signal by performing a gamma correction of an input digital image signal by using the look-up table stored in the color transformation memory and outputting the PDP digital image signal; and a color correction matrix unit for performing a color correction of the generated PDP digital image signal by using a predetermined matrix according to an APC level of input image stored in the color transformation memory.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a color transforming device for transforming a color of an image based on brightness information of the image in accordance with an embodiment of the present invention;

FIG. 2 is a block diagram illustrating a PDP operating device having the color transforming device as shown in FIG. 1;

FIG. 3 is a block diagram of the color transforming device in FIG. 2 in accordance with one embodiment of the present invention;

FIG. 4 is a block diagram of the color transforming device in FIG. 2 in accordance with another embodiment of the present invention; and

FIG. 5 is a graph for explaining a gamma curve correction of a gamma correction unit in FIG. 4.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

Certain embodiments of the present invention will be described in greater detail with reference to the accompanying drawings.

In the following description, the same drawing reference numerals are used for the same elements even in different drawings. The matters defined in the description such as a detailed construction and elements are provided to assist in a comprehensive understanding of the invention. Thus, it is apparent that the present invention can be carried out without those defined matters. Also, well-known functions or constructions are not described in detail since they would obscure the invention in unnecessary detail.

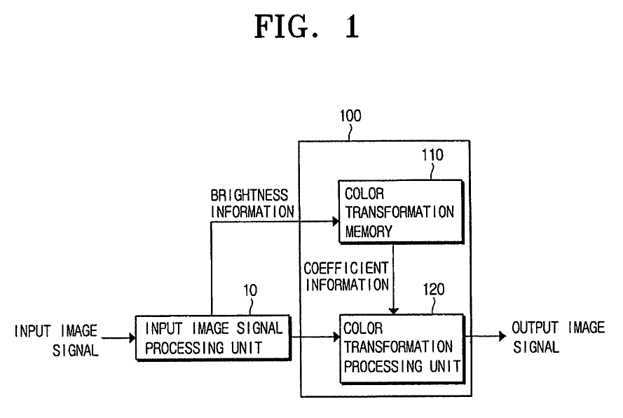

FIG. 1 is a diagram illustrating a color transforming device using brightness information of an image in accordance with an embodiment of the present invention. Referring to FIG. 1, the color transforming device 100 includes a color transformation memory 110 and a color transformation processing unit 120.

An input image signal processing unit 10 in FIG. 1 provides brightness information of an input image signal to the color transformation memory 110.

The color transformation memory 110 stores various coefficient information required for performing a color transformation at the color transformation processing unit 120. The color transformation memory 110 provides the coefficient information corresponding to input brightness information to the color transformation processing unit 120.

The color transformation processing unit 120 performs color transformation of each pixel of a digital image signal by using the coefficient information received from the color transformation memory 110. After performing the color transformation, the color transformation processing unit 120 outputs the color transformed image signal.

Alternatively, the input image signal processing unit 10 may provides brightness information of the input image to the color transformation processing unit 120. In this situation, the color transformation processing unit 120 provides the received brightness information of the input image to the color transformation memory 110, and the color transformation memory 110 provides coefficient information corresponding to the received brightness information to the color transformation processing unit 120.

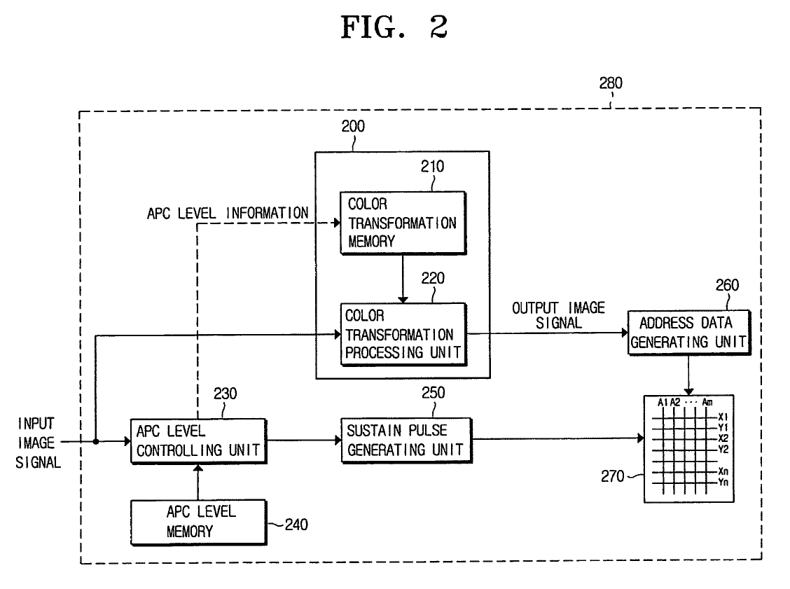

FIG. 2 is a diagram of a PDP operating device including the color transforming device using the brightness information. As shown in FIG. 2, the PDP operating device 280 includes an APC level controlling unit 230, an APC level memory 240, a color transforming device 200, a sustain scan pulse generating unit 250, an address data generating unit 260, and a PDP 270. The color transforming device 200 includes a color transformation memory 210 and a color transformation processing unit 220.

The APC level controlling unit 230 detects a load factor by using a RGB image signal input from an external source, and determines an APC level required for operating the PDP 270 based on the detected load factor. Also, the APC level controlling unit 230 provides information related to the APC level to the color transformation memory 210. Furthermore, the APC level controlling unit 230 calculates and outputs the number of sustain pulses corresponding to the determined APC level and a bandwidth of an address pulse of each sub field. As the APC level corresponding to the load factor and the number of sustain pulses are determined by referring to the APC level memory 240, the APC level memory 240 stores the number of sustain pulses of corresponding APC level.

The sustain pulse generating unit 250 receives the calculated number of sustain pulses and an address pulse bandwidth of each sub field, and generates a subfield arrangement structure corresponding to the calculated number of sustain pulse and the bandwidth. Also, the sustain pulse generating unit 250 generates a sustain pulse and a scan pulse based on the generated subfield arrangement structure and provides the sustain pulse and the scan pulse to the scan electrodes (X1, X2, . . . , Xn) and sustain electrodes (Y1, Y2, . . . , Yn).

The color transformation processing unit 220 performs color transformation of the input digital image signal according to the APC level by using a predetermined conventional color transformation algorithm, and outputs a color transformed image signal. The color transformation processing unit 220 receives coefficient information according to the APC levels required for using the predetermined transforming algorithm from the color transformation memory 210.

The address data generating unit 260 generates address data corresponding to the color transformed image signal output from the color transforming device 200 and provides the generated address data to the address electrodes (A1, A2, . . . An) of the PDP 270.

As described above, a scan pulse voltage is applied to at least one of the scan electrodes (X1, X2, . . . , Xn) and the sustain electrode (Y1, Y2, . . . , Yn), and an address voltage is applied the address electrodes for generating discharge at a cross point between the pair of the scan electrode and the sustain electrode and the address electrode. By the generated discharge, an address operation is generated for varying electrical characteristics of the cross point and discharge is timely generated. After generating the address operation and the discharge, a sustain operation is generated by supplying a sustain pulse voltage between the scan electrode and the sustain electrode for generating a discharge only at a location where the electric characteristics of scan electrode and sustain electrode are varied.

The color transforming device 100 is implemented in the PDP operating device 200 in the embodiment of the present invention. However, the color transforming device 100 may be implemented in the LCD or the CRT display devices.

FIG. 3 is a block diagram showing a color transforming device in accordance with one embodiment of the present invention. As shown in FIG. 3, the color transforming device 300 includes a color transformation memory 310 and a color transformation processing unit 320. The color transformation processing unit 320 includes a first gamma correction unit 330, a color transformation matrix 340, and a second gamma correction unit 350. In one embodiment, the color transforming device 300 corrects the gamma of the PDP by performing a gamma correction twice by using the first and the second gamma correction units 330 and 350.

The first gamma correction unit 330 maps digital values of an input image signal to normalized brightness values of input signal. The normalized brightness values are defined based on a conventional gamma curve. The mapped values are stored as a lookup table format. The first gamma correction unit 330 may be implemented by using a nonvolatile memory such as a read only memory (ROM). Also, the first gamma correction unit 330 may be implemented by using a single ROM or a plurality of ROMs.

The first gamma correction unit 330 transforms an input digital RGB image signal (dR, dG, dB) to linear RGB image signal (RsRGB, GsRGB, BsRGB) output by a gamma characteristic of input signal. The linear RGB image signal is the normalized brightness value. The linear RGB image signal is output to the color transformation matrix unit 340. The gamma characteristic is a relation between an input digital image signal and an output brightness. In one embodiment, the input digital RGB image signal (dR, dG, dB) is 8-bit signal and each value of the input digital RGB image signal has an integer value in a range of 0 to 255.

The first gamma correction unit 330 may perform the gamma conversion by using a look-up table (LUT) or a numeral operation. In one embodiment of the present invention, the LUT is used for gamma conversion.

Specifically, the first gamma correction unit 330 receives sRGB image signal from external and generates a brightness value of the digital image signal identical to a brightness value of the conventional gamma 2.2 curve. Next, the first gamma correction unit 330 standardizes and outputs the generated brightness as a value in a range of 0 to 1.

The linear RGB image signal (RsRGB, GsRGB, BsRGB) output from the first gamma correction unit 330 has a linear relation with output brightness of each channel defined by the input RGB image signal and it is expressed as a value in a range of 0 to 1.

The color transformation matrix unit 340 generates color transformed linear RGB image signal (RPDP, GPDP, BPDP) which are suitable for the PDP by performing a 3×3 matrix conversion of linear RGB image signals (RsRGB, GsRGB, BsRGB) and outputs the color transformed linear RGB image signal to the second gamma correction unit 350. Each value of R, G, and B of the linear RGB image signal has a linear relation with brightness of each PDP channel.

The color transformation matrix unit 340 uses a following equation to perform the matrix conversion.

$$( \begin{matrix}{R}_{PDP} \\ {G}_{PDP} \\ {B}_{PDP}\end{matrix} ) = {( \begin{matrix}{X}_{r , PDP} & {X}_{g , PDP} & {X}_{b , PDP} \\ {Y}_{r , PDP} & {Y}_{g , PDP} & {Y}_{b , PDP} \\ {Z}_{r , PDP} & {Z}_{g , PDP} & {Z}_{b , PDP}\end{matrix} )}^{- 1} ( \begin{matrix}{X}_{r , D65} & {X}_{g , D65} & {X}_{b , D65} \\ {Y}_{r , D65} & {Y}_{g , D65} & {Y}_{b , D65} \\ {Z}_{r , D65} & {Z}_{g , D65} & {Z}_{b , D65}\end{matrix} ) ( \begin{matrix}RsRGB \\ GsRGB \\ BsRGB\end{matrix} ) \qquad [ Equation 1 ]$$

In the Equation 1, X, Y and Z represent a value of a measured data of color. That is, X, Y and Z are a tristimulus value and they are fixed as a predetermined value according to the APC level. In a special case, an identical matrix is used for all APC levels.

X_{PDP}, Y_{PDP} and Z_{PDP} are tristimulus values measured at a PDP, and X_{D65}, Y_{D65} and Z_{D65} are tristimulus values defined in sRGB standard color space. Xᵣ, Yᵣ and Zᵣ are tristimulus values of a maximum red color. That is, if a color is expressed as (dR, dG, dB), the maximum red color is a color (255, 0, 0) and Xᵣ, Yᵣ and Zᵣ represent the maximum red color (255, 0, 0). X_{g}, Y_{g} and Z_{g} are tristimulus values of a maximum green color (0, 255, 0). X_{b}, Y_{b} and Z_{b} are tristimulus values of a maximum blue color (0, 0, 255).

The second gamma correction unit 350 converts the input PDP linear RGB image signal (R_{PDP}, G_{PDP}, B_{PDP}) to be suitable to a gamma characteristic of the PDP panel by use of the look-up table stored according to each APC level in the color transformation memory 310, and outputs the converted PDP linear RGB image signal (dR′, dG′, dB′). The image signal finally output from the second gamma correction unit 350 is a digital value transmitted to the PDP.

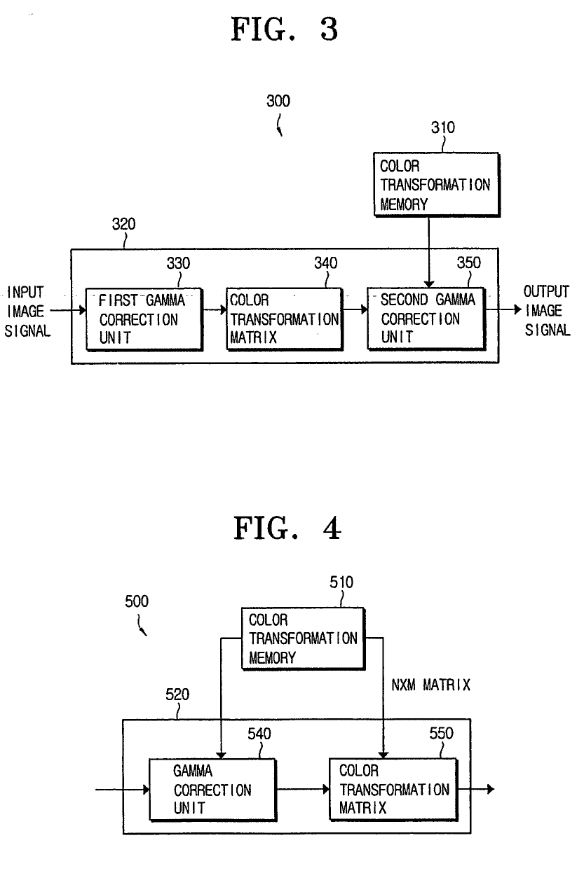

FIG. 4 is a block diagram of a color transforming device in accordance with another embodiment of the present invention. By referring to FIG. 4, the color transforming device 500 includes a color transformation memory 510 and a color transformation processing unit 520. The color transformation processing unit 520 includes a gamma correction unit 540 and a color calibration matrix unit 550.

The gamma correction unit 540 generates a PDP digital image signal having a brightness value identical to a brightness value defined from an input digital image signal, and outputs the generated PDP digital image signal to the color calibration matrix unit 550. The gamma correcting unit 540 performs a gamma correction by using the look-up table stored according to each APC level at the color transformation memory 510.

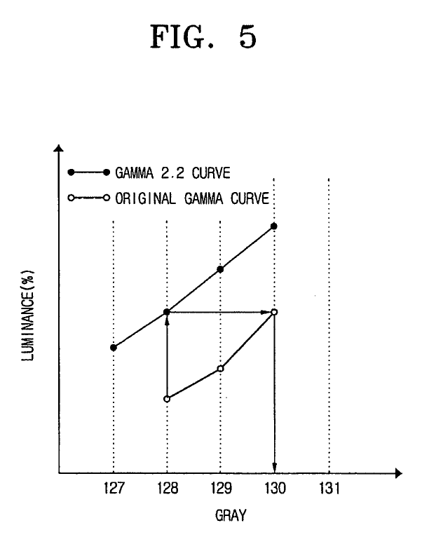

FIG. 5 is a graph for explaining a gamma correction performed at the gamma correcting unit of FIG. 4. As shown in FIG. 5, if a gray level of sRGB input digital image signal is 128, a gray level of output image having a brightness value identical to a brightness value of a gamma curve 2.2 is 130.

The color calibration matrix unit 550 performs a color calibration of the digital image signal having gamma characteristics of the PDP by using color transformation N×M matrix stored in the color transformation memory 510. That is, the color calibration matrix unit 550 converts a digital image signal to a digital value to be transmitted to the PDP. A size of the color calibration N×M matrix may be varied according to the APC level.

As mentioned above, the present invention increases effect of color transformation by implementing the color transforming method based on brightness of input image which is an image quality improving method.

Also, the present invention provides a method of color transformation suitable to a display device having a function of automatically controlling outputting brightness according to brightness of input image. When the present invention is implemented to the PDP, color information of input image signal is accurately reproduced by performing the color transformation according to the APC level of input image.

The foregoing embodiment and advantages are merely exemplary and are not to be construed as limiting the present invention. The present teaching can be readily applied to other types of apparatuses. Also, the description of the embodiments of the present invention is intended to be illustrative, and not to limit the scope of the claims, and many alternatives, modifications, and variations will be apparent to those skilled in the art.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A color transforming device using brightness information of an image, comprising:
a color transformation memory for storing coefficient information to process a color transformation of an input image corresponding to a brightness of the input image; and
a color transformation processing unit for correcting a color of the input image by using the coefficient information stored in the color transformation memory and outputting the color corrected input image.

2. A display device using brightness information of an image, comprising the color transforming device of claim 1.

3. A display device including a color transforming device using brightness information of an image, comprising:
a color transformation memory to store coefficient information to process a color transformation of an input image corresponding to an auto power control (APC) level of the input image; and
a color transformation processing unit to correct a color of the input image by using the coefficient information corresponding to the APC level of the input image.

4. The display device of claim 3, further comprising:
an APC level controlling unit to detect a load factor by using a RGB image signal input, to determine the APC level required to operate the display device based on the detected load factor, and to provide information of the determined APC level to the color transformation memory; and
an address data to generate unit for generating address data corresponding to the color corrected input image signal from the color transformation processing unit.

5. The display device of claim 3, wherein the color transformation memory stores the coefficient information as a look-up table corresponding to the APC level, and
the color transformation processing unit comprises,
a first gamma transformation unit to output a linear RGB image signal transformed according to a gamma characteristic of an input digital RGB image signal;
a color transformation matrix unit to generate a color transformed linear RGB image signal by performing a predetermined matrix transformation of the linear RGB image signal from the first gamma transformer and to output the color transformed linear RGB image signal; and
a second gamma transformation unit to transform the color transformed linear RGB image signal to a digital RGB image signal base upon a gamma characteristic of the display device by using the look-up table of the corresponding APC level stored in the color transformation memory.

6. The display device of claim 5, wherein the color transformation matrix unit uses a predetermined matrix for the matrix transformation and the predetermined matrix is varied based upon the APC level.

7. The display panel device of claim 5, wherein the input digital RGB image signal comprises 8-bit signal.

8. The display device of claim 3, wherein the color transformation memory stores coefficient information according to an APC level stored in a form of a look-up table to correct a gamma characteristic and plural of matrix information based upon an APC level for color transformation, and
the color transformation processing unit comprises,
a gamma correction unit to generate a digital image signal corrected to have identical gamma character comparing to an input signal by performing a gamma correction of an input digital image signal by using the look-up table stored in the color transformation memory and to output the PDP digital image signal; and
a color correction matrix unit to perform a color correction of the generated digital image signal by using a predetermined matrix according to an APC level of input image stored in the color transformation memory.

9. The display device of claim 3, wherein the display device is a plasma display panel (PDP).

10. A method of color transforming using brightness information of an image, comprising:
storing coefficient information in order to process a color transformation of an input image corresponding to brightness of the input image; and
correcting a color of the input image by using the coefficient information.

11. The method of claim 10, wherein the correcting the color of the input image is performed based upon an auto power control (APC) level of an input image.

12. The method of claim 11, further comprising:
outputting the corrected color input color image to a display device.

13. The method of claim 11, wherein the display device is a plasma display panel (PDP).

14. A method for transforming a color using brightness information of an image, comprising:
storing coefficient information to process a color transformation of an input image based on an auto power control (APC) level of the input image; and
correcting a color of the input image by using the coefficient information in accordance with the APC level of the input image.

15. The method of claim 14, further comprising:
outputting the color corrected input image to a display device.

16. The method of claim 15, wherein the display device is a plasma display panel (PDP).
